(19) United States
(12) Patent Application Publication
(10) Pub. No.: US 2008/0286081 A1
(43) Pub. Date: Nov. 20, 2008

(54) Truck lifted rear-load transfer system

(76) Inventor: Thomas Inard Reed, III, Aurora, CA (US)

Correspondence Address: BARBER LEGAL, P.O. BOX 16220, GOLDEN, CO, 80402-6004, US

(21) Appl. No.: 12/148,129

(22) Filed: Apr. 16, 2008

Related U.S. Application Data
(63) Continuation-in-part of application No. 11/336,135, filed on Jan. 19, 2006.

(51) Int. Cl. B65F 3/26; H01L 21/677

(52) U.S. Cl. 414/491; 414/800

(57) ABSTRACT

A roll-off waste container having a gate at one end, and lifting devices using the power equipment of a garbage truck to raise one end of the container to approximately the level of the truck's hopper and container gate and the other end of the container higher so that waste within the container may slide out. A mechanical link may be attached and in use, the link may grab or connect to the container to be raised or a cable link may be attached to the truck hydraulics, and the cable may be attached to the container to be raised.

### REFERENCE TO RELATED APPLICATIONS

This application claims the priority and benefit of co-pending U.S. patent application Ser. No. 11/336,135 in the name of the same inventor, Thomas Reed III, having the same title: “Truck Lifted Rear-Load Transfer System”, the entire disclosure of which in incorporated herein by this reference.

### FIELD OF THE INVENTION

This invention relates to generally to waste handling and specifically to a system by which roll-off containers may transfer wastes to a rear-load garbage truck.

### BACKGROUND OF THE INVENTION

For large quantities of waste, the normal commercial trash container (usually called a “DUMPSTER”, this exact mark is registered to Dempster Systems Inc, Knoxville Tenn., having no relationship to the present applicant. Numerous other marks make use of the word “DUMPSTER”) a metal box roughly two meters tall by three meters long by two meters from front to back is quite often inadequate. For example, construction sites often generate waste which is both of considerably greater volume and may be of a size such that one dimension or more will not fit into a standard trash bin.

Examples of such “DUMPSTER” style containers include U.S. Pat. No. 3,262,589 to Kolling on Jul. 26, 1966, which teaches a small container for use with a rear-load truck in the normal manner. It lacks any gate, and also lacks roll-off equipment in the form of no hook for a hoist truck and no rollers.

U.S. Pat. No. 3,709,389 to Steltz on Jan. 9, 1973 teaches another small container having no back gate: it merely has a small hatch which does not reach the sides nor even the bottom of the interior and thus utterly precludes any roll-off emptying by a hoist truck tilting it. The Steltz patent thus teaches away from the fundamental principle of operation of roll-off containers, which is being tilted by a hoist truck and thus emptied through a full side to side to bottom gate. Since it teaches away from this, it Steltz cannot even be combined with roll off containers: “If the proposed modification or combination of the prior art would change the principle of operation of the prior art invention being modified, then the teachings of the references are not sufficient to render the claims prima facie obvious. In re Ratti, 270 F.2d 810, 123 USPQ 349 (CCPA 1959)”

U.S. Pat. No. 3,765,555 to McKenzie et al on Oct. 16, 1973 teaches another small container lacking rollers, a hoist truck usable hook, extended length, a Y cable connection and so on and so forth.

U.S. Pat. No. 6,702,135 to Pickler on Mar. 9, 2004, teaches a front load container with roll-off container features. For example, it appears to have sleeves allowing front loading into a front load garbage truck, but lacks rollers of a roll off containers. Since it is a front load container, it is necessarily constrained in size, as shown in the diagrams and by such phrases in the text as “capacity may be somewhat increase”. Worse, the sleeves of the Pickler device render it unserviceable by a rear-load garbage truck, a problem common to known front load “Dumpster” type devices. Since the front load sleeves make it impossible to operate with a rear load truck, and since it quite plainly teaches in favor of front loading (see the diagrams), the Pickler device also falls within the strictures of In re Ratti, 270 F.2d 810, 123 USPQ 349 (CCPA 1959): “If the proposed modification or combination of the prior art would change the principle of operation of the prior art invention being modified, then the teachings of the references are not sufficient to render the claims prima facie obvious.”

For this purpose, a large standard size is commonly used, the “roll-off” container. The roll-off trash container may be the same size as a standard container with the roof and some of the upper walls removed, but normally may be other sizes normally several times larger than a normal commercial trash bin. The roll-off container is designed so that it may be rolled on and off the back of a specially equipped flat-bed truck. The normal manner of employment of a roll-on roll-off container may be understood by reference to FIG. 1 through FIG. 4 of U.S. Pat. No. 6,332,746, issued Dec. 25, 2001 to Lang et al, a convenient example of the use of a hoist truck. A large truck with a specially equipped hoist backs up to the trash container from one end. The hoist is raised and attached to the container and the container is slowly lifted until it is suspended along the length of the hoist. The hoist/container combination is then lowered back to the bed of the truck. It is significant that the container is thus left on the bed of the truck behind the cab, it is NOT emptied into the truck: the truck has no separate waste holding container. The truck driver drives the truck with the container on its bed to the appropriate sanitary landfill facility for disposal of the waste within the container. Then the driver returns to the work-site and repeats the same process in reverse as he returns the roll-off container to those who require it as a trash receptacle.

There are numerous complications and uncertainties in this process. First and foremost, the roll-off container may be attached at the front end to a building: such an arrangement is common behind supermarkets, department stores and other large establishments. In this case, the driver is forced to perform the following operations: back up to the accessible end of the container, disconnect the roll-off container from the building, hook the accessible back end of the container to the hoist, lift it up or pull it on its rollers, move the truck a short distance, unhook the container from the hoist, drive the truck around and back it up to the front end of the container, hook the front end of the container to the hoist, raise it onto the hoist, lower the hoist to the bed of the truck, and then begin driving the container to the landfill. The entire process must be reversed in order to put the container back in place when the driver returns.

The expensive hoist-equipped truck is not as flexible as the normal rear-load garbage truck: since it has no built in waste container, and compaction blades, it cannot be used in the residential setting; since it also lacks a mechanism for lifting of a conventional commercial waste bin, it cannot be used with such bins.

Commonly, it is necessary to provide special devices on the roll-off hoist truck in order to cover the open container, without such devices the truck may be in violation of the law, may be charged a premium at the landfill facility, or may allow waste to blow out of the container during transit.

In addition, during the period of time when the driver is making the round trip with the container to the landfill and back, the container is unavailable to the end user. Thus the disposal contractor must add to the cost of the hoist truck by committing an empty container to each truck at the start of the day's route in order to allow “daisy-chaining” of the individual stops on the route. Even then, however, the truck and driver must after each stop on the route make a substantial trip to the landfill. In most major metropolitan areas, the landfills are located at some distance from the city center, thus making for a normally long round trip. Some major metropolitan areas suffer from 24 hour congestion, in which areas the number of runs a single driver can make in a single day may dwindle to a few, or even one.

In terms of energy usage, a large truck making multiple daily round-trips to the landfill represents a large use of petroleum products or other energy sources. In every metropolitan area, there are fleets of such trucks doing this. Thus, the present invention offers the ability to provide great energy savings. In addition to fuel, the environmental impact of this is quite large. The emissions generated by a single truck may be greatly reduced by use of the present invention. Such airborne pollution is becoming a greater issue due to global warming, depletion of the ozone layer, metropolitan growth and an increased understanding of the health hazards of such air pollution.

By contrast, it should be noted that the smaller commercial waste bin (“DUMPSTER”) is simply lifted up by a garbage truck, the trash received, and the bin is put back down. Small compactors (known examples include a 6 yard container) may also be lifted by means of a cable powered by a garbage truck. These are not roll-off containers, lacking various necessary equipment for use with roll-off trucks, instead, garbage trucks for handling of the two meter by three meter by two meter commercial waste bin and similar sizes may be either “front loading” in which the bin is lifted over the cab of the truck and inverted, or “rear-loading.” The rear-load garbage truck is the familiar type of garbage truck often used in residential settings. When modified to handle a commercial waste bin, the bin is lifted at the back of the truck and the trash is transferred to the compaction blades at the back of a normal read-load garbage truck, and the bin is put back down. In addition, such trucks are covered and thus may be advantageously equipped with compaction blades. Such compaction blades are invaluable in reducing trips to the landfill: the volume of the wastes handled may be reduced by a factor of 10 to 1 or more from the volume as it is left in the trash can by the residential or commercial customer. Such compaction is obviously impossible for a hoist truck which simply carries the large trash container as it was filled by the customer. Thus, a hoist truck must of necessity carry each and every individual roll-off container which it services all the way to a waste facility, empty it, and then return it before moving on to the next container.

U.S. Pat. No. 6,296,132 issued Oct. 2, 2001 to Picker teaches a universal DUMPSTER which is usable in several different modes. It may be used as a roll-off, as a front load, carried on a trailer, etc. It teaches doors at one end and an open top. However it does not teach connection to a conventional rear-load truck and so on.

U.S. Pat. No. 5,607,277 issued Mar. 4, 1997 to Zopf teaches a garbage can which is picked up by the waste truck. The can in the '277 patent is emptied into an intermediate container. Again, most of the features taught by the present invention are missing from this item of prior art.

U.S. Pat. No. 5,427,497 issued Jun. 27, 1995 to Dillman teaches a horizontal surge/storage silo different from the present invention because rear-load garbage trucks may not be used and for other reasons.

U.S. Pat. No. 5,348,125 issued Sep. 20, 1994 to Stribling teaches a self contained hydraulic power unit for waste compactors. An electrical connection is made from a vehicle to the hydraulic power unit on the compactor, and the electricity used to drive the compactor. No transfer of waste is suggested, no roll-off equipment is suggested, and the device deals with stationary compactors.

U.S. Pat. No. 5,317,963 issued Jun. 7, 1994 and U.S. Pat. No. 5,083,510 issued Jan. 28, 1992 to Hohlt teach another type of stationary compactor, seemingly in the smaller commercial size waste bin.

U.S. Pat. No. 5,214,594 issued May 25, 1993 to Tyler et al teaches a “network” for multiple trash compactors and measurement of pressure on the blade in order to determine fullness.

U.S. Pat. No. 5,092,233 issued Mar. 3, 1992 teaches the TRASH COLLECTION AND STORAGE SYSTEM which something very like an airport jetway. An indoor trash hopper or compactor feeds wastes to the conveyor system inside the device, the device itself pivots outwards from the building and may extend as well, in order to match up with a rear-load garbage truck and convey waste thereto. On the indoors side of the device, a hinged platform may be raised or lowered (see FIGS. 7A, 7B). Overall there are numerous structural and conceptual differences between this device and the present invention: lack of any roll-off container equipment, a lack of vertical adjustment to match with the rear-load truck, the fact that this is a “through the wall” system, lack of a compaction blade as the to-truck-transfer mechanism, and so on. Most particularly, this system cannot possibly be pivoted upwards to gravity feed. In addition, since this is a building waste chute rather than a mobile container, it is a different art.

U.S. Pat. No. 4,643,087 issued Feb. 17, 1987 to Fenner et al teaches a system for measuring fullness of a waste compactor container. Other than being an example of a container with a compactor/blade, it does not disclose features of the present invention: pivot and lift of a roll-off container, and the like.

U.S. Pat. No. 4,557,658 issued Dec. 10, 1985 and U.S. Pat. No. 4,372,726 issued Feb. 8, 1983 to Lutz teach another waste compactor container, this time with two compartments for wastes. It is otherwise unrelated to the invention.

U.S. Pat. No. 3,787,830 issued Jan. 22, 1974 to Cato et al teaches as trap door type arrangement to indicate when a compactor/container is full of trash, and is otherwise unrelated to the invention.

It is also known in the art, though not disclosed by applicant's search of the US PTO database of granted patents, to have a container having an ejector blade and wet line ports by which to receive hydraulic power. These devices are used in the known method of cleaning of such containers (hoisting the container onto a truck, conveying it to a land-fill facility, and raising it to let waste slide out the back at a landfill). On occasion, the waste refuses to slide out the back. At that time, the ability to eject the waste by forcing the blade down the length of the container is beneficial. However, there is no known art in which a roll-off container may raise and tilt to gravity feed a hopper or otherwise transfer wastes to a garbage truck.

It would be advantageous to allow rear-load garbage trucks, with their advantage of compaction blades, covered waste holding spaces, and flexibility as well, to be able to service roll-off containers. Such hoppers are capable of 10:1 compaction or more, and are equipped with blades which grab items in the hopper and pull them further in, compacting as they go. It would further be advantageous to allow service by rear-load, front-load and hoist trucks. It would further be advantageous to provide a means by which one truck could service a plurality of containers before making a single round trip to the landfill. It would further be advantageous to allow transfer of wastes from containers to rear-load trucks. It would further be advantageous to avoid the nuisance and uncertainty of hoisting containers onto roll-off trucks for conveyance if they can be hoisted and emptied immediately, and wastes compacted.

The only items known to be of interest is that of the same inventor, Thomas Reed, entitled REAR-LOAD TRANSFER SYSTEM and issued as U.S. Pat. No. 6,709,219 on the date Mar. 23, 2004.

That invention teaches that a container may have large hydraulic cylinders giving it the structures to lift itself off of the ground and by that means allowing transfer of the waste in the container to a rear-load truck.

The cost of hydraulic cylinders may be high. For that reason, it is advantageous to eliminate the cost and weight of hydraulic cylinders if possible.

One proposal is that a cable may be attached to the transfer blade to pull the transfer blade to urge wastes out of the container into the rear-load truck. That suggestion does not address the issue of raising the container, and pulling the transfer blade by means of a cable has marked disadvantages: the blade may not be aligned by an asymmetrical pull, the cable is difficult to attach to the blade owing to the blade starting the operation at the distal end of the container, the cable may have to traverse over mounded, sharp edged, and structurally strong trash in the container and so on.

### SUMMARY OF THE INVENTION

General Summary

The present invention teaches a large waste container, especially a roll-off waste container, having a full gate at one end, and lifting devices using the power equipment of the truck to raise the first end of the container to approximately the level of a garbage truck's hopper (if it is originally lower than the hopper) while the second end of the container is lifted higher than the hopper. Wastes are removed when the container is raised and tilted and the wastes are transferred by gravity feed to a garbage truck.

Raising of the rear end of the container and gate may be accomplished using the extensive high power equipment of the typical garbage truck. A cable link may be attached to the truck's hydraulics, such as the hydraulic winch cylinder atop the truck, the blade cylinders or another cylinder of the truck, and the cable may be attached to the container to be raised.

The present invention may be used industrially, in construction, in residential settings, and commercially. The invention may be opened at sides or tops to meet the user's waste disposal needs, and may be connected to a building by a trash chute. Allowing servicing of roll-off containers by conventional garbage trucks as several advantages: it reduces the number of special roll-off hoist trucks required, it allows the garbage trucks to compact the wastes after transfer and it permits covered carrying of waste loads without special equipment.

Energy savings are a major feature of the present invention. By allowing a single rear-load truck to compress waste from multiple roll off containers, the device allows a single trip to waste disposal facilities.

The apparatus may advantageously be substantially the same width as the hopper of a rear-load garbage truck. The invention may also replace known compactors in use by large commercial establishments, either free-standing compactors, or compactors attached to buildings, due to the fact that the invention also has compactor embodiments.

Summary in Reference to claims

It is therefore a first aspect, advantage, objective and embodiment of the present invention to provide a waste handling system for use with a rear-load garbage truck having a waste receiving hopper at a first height, and having waste handling power equipment having a first position and a second position, the waste handling system comprising:
an operative physical link having a connector; the operative physical link connected to such power equipment;
a roll-off container comprising:
   roll-off equipment including a first hook, and at least one skid or roller;
   a body having first and second ends and first and second sides;
   a hard point dimensioned and configured to accept the connector;
the operative physical link dimensioned and configured such that when the connector of the operative physical link is attached to the hard point and such power equipment is changed from such first position to such second position, at least the second end of the body is lifted to approximately such height of such hopper.

It is therefore yet another aspect, advantage, objective and embodiment of the present invention to provide a waste handling system wherein the width of the hopper and the width of the body are approximately equal.

It is therefore yet another aspect, advantage, objective and embodiment of the present invention to provide a waste handling system wherein the width of the hopper and the width of the body are in the range from 70 to 72 inches.

It is therefore yet another aspect, advantage, objective and embodiment of the present invention to provide a waste handling system wherein the waste container further comprises:

a gate located at the second end of the body.

It is therefore yet another aspect, advantage, objective and embodiment of the present invention to provide a waste handling system wherein the second end of the body is lifted substantially higher than the height of the hopper.

It is therefore yet another aspect, advantage, objective and embodiment of the present invention to provide a waste handling system wherein the power equipment comprises a hydraulic cylinder.

It is therefore yet another aspect, advantage, objective and embodiment of the present invention to provide a waste handling system wherein the hydraulic cylinder comprises a winch cylinder.

It is therefore yet another aspect, advantage, objective and embodiment of the present invention to provide a waste handling system wherein the power equipment comprises a compactor blade.

It is therefore yet another aspect, advantage, objective and embodiment of the present invention to provide a waste handling system wherein the operative physical link comprises a cable.

It is therefore yet another aspect, advantage, objective and embodiment of the present invention to provide a waste handling system wherein the hard point comprises one member selected from the group consisting of: a hook, an eyelet, an aperture, a yoke, a cable, and combinations thereof.

It is therefore yet another aspect, advantage, objective and embodiment of the present invention to provide a waste handling system wherein the operative physical link further comprises a lock.

It is therefore yet another aspect, advantage, objective and embodiment of the present invention to provide a waste handling system wherein the first hook further comprises at least one member selected from the group consisting of: a roll-off hoist arm receiver hook, a roll-off cable receiver hook and combinations thereof.

It is therefore yet another aspect, advantage, objective and embodiment of the present invention to provide a waste handling system wherein the container further comprises at least one cross beam reinforcing the sides of the container body.

It is therefore yet another aspect, advantage, objective and embodiment of the present invention to provide a waste handling system for use with a rear-load garbage truck having a waste receiving hopper at a first height, and having waste handling power equipment having a first position and a second position, the waste handling system comprising:
an operative physical link having a connector; the operative physical link connected to such power equipment;
a roll-off compactor comprising:
   a body having first and second ends;
   roll-off equipment including a first hook, and at least one skid or roller;
   a hard point dimensioned and configured to accept the connector;
the operative physical link dimensioned and configured such that when the connector of the operative physical link is attached to the hard point and such power equipment is changed from such first position to such second position, at least the second end of the body is lifted to approximately such height of such hopper.

It is therefore yet another aspect, advantage, objective and embodiment of the present invention to provide a method of transferring waste from a container having a trunnion bar at a first end and having a second end and hard point to a standard garbage truck having a hopper at a first height above the ground and at least one hydraulic cylinder, the process comprising the steps of:
1) attaching the trunnion bar on the container to the hopper of the truck;
2) attaching a cable to the hard point of the container and to the hydraulic cylinder of the truck;
3) applying force to the cable from the cylinder so as to rotate the container vertically about the trunnion bar; X
4) raising the second end of the container to a height higher than the height of the hopper, whereby the container gravity feeds into the hopper.

### BRIEF DESCRIPTION OF THE DRAWINGS

FIG. 1 is a side view of a first cable lift embodiment of the invention.

FIG. 2 is an end view of the first embodiment of the invention.

FIG. 3 is a side view of the first embodiment of the invention showing details of the gate.

FIG. 4 is an elevational perspective view of the first embodiment of the invention with the gate partially open.

FIG. 5 is a side view of the first embodiment of the invention in a first raised position.

FIG. 5b is a side view of the first embodiment of the invention in a second raised position to encourage gravity transfer of waste.

FIG. 6 is a perspective view of a second embodiment of the invention, a compactor embodiment.

FIG. 7 is an elevational perspective view of a larger embodiment of the invention having higher sides.

FIG. 8 is a side view of a third embodiment of the invention having a different bar arrangement in a raised position with the “nose” of the invention further into the hopper.

FIG. 9 is a side view of a hoist truck and the container of the invention, showing the invention in the process of being lifted onto the hoist truck for conventional roll-off processing.

FIG. 9b is a partial side view of the invention on the hoist truck, showing it in the position for conventional conveyance.

### INDEX TO REFERENCE NUMERALS

Waste container 100
Trunnion bar 102
Hard point/lifting hook 104
Roll-off runner 106
Roll-off attachment point, A frame 108
Roll-off attachment point, hook 110
Roller 200
Inner rollers/rail rollers 202
Gate hinge 204
Gate lock arms 300
Gate lock swing arms 302
Open top container body 304
Roll-off attachment point 400
Gate with cross beam 402
Y cable 404
Rib 406
Rear-load truck 520
Lift cable 522
Container 524
First raised position 526
Hydraulic cylinder/waste handling power equipment 528
Second raised position 530
Front side 532
Hopper 534
Side waste load door 600
Folding top door 602
First end 701
Second end 703
Hoist truck 902
Hoist 904
Container 906
Truck bed 908

### DETAILED DESCRIPTION

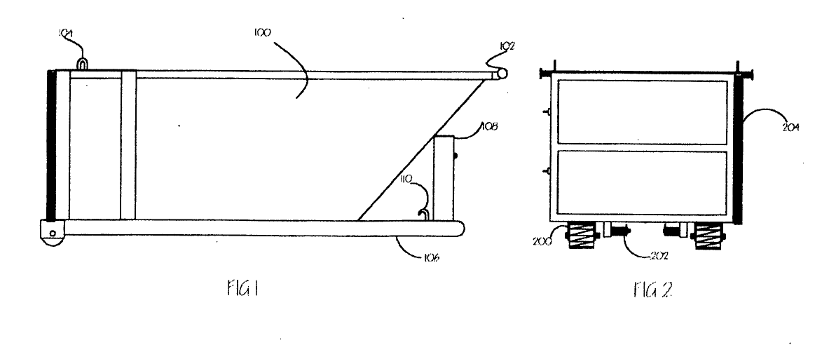

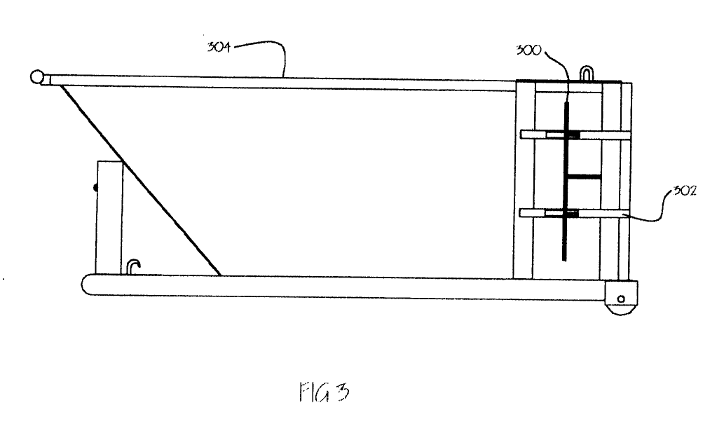

FIG. 1 is a side view of a first cable lift embodiment of the invention, a 10 yard open top container. FIG. 2 is an end view of the first embodiment of the invention.

Waste container/body 100 has a sloped “nose” end having trunnion bar 102, which may advantageously be of a standard size used on waste containers used with rear load, front load and various types of waste trucks. Unlike a front load container, this end should be sleeve-less, so as to allow the end to be used with a rear-load garbage truck hopper.

Hard point/lifting hook 104 may be disposed either at the second end of the container or substantially distal from the first end, at a distance providing a sufficient lever arm (torque) to allow the container to be rotated vertically about the axis of trunnion bar 102 when the force generated by normal hydraulic or electrical equipment of a garbage truck is applied at the hard point 104. The hard point may advantageously be a Y-cable connector which in turn attaches on both sides of the container. The container is then braced across the width at that point so that the sides are not pulled inward and collapsed by the weight of the container itself when lifted.

Roll-off runner 106 allows the device to slide in conjunction with roller 200, for example when being hoisted or moved by a hoist truck. Roll-off attachment point, A frame type, 108 and/or roll-off attachment point, hook type, 110, allow the device to be attached and lifted by a roll off truck of either the hoist type or the cable type is suitably attached.

Rail rollers 202 allow the underside of the device to easily roll on the rails present on the bed of a typical hoist truck. Gate hinge 204 allows the second end of the device to be opened and emptied in a conventional roll off manner by a roll off truck. Note that a smaller hatch would not be sufficient for roll off style emptying, as the garbage within would be caught on the sides: a full gate which extends to the bottom of the device and completely from side to side is necessary.

Thus the term “roll-off” equipment as used herein largely refers to a full sized gate, rollers, runners, and a hook suitable for use with a hoist truck's hoist.

Note that the device of the invention may thus be emptied by tilting in either of two opposite directions: toward the nose end which attaches to a rear-load truck hopper or toward the gate end when tilted by a hoist truck.

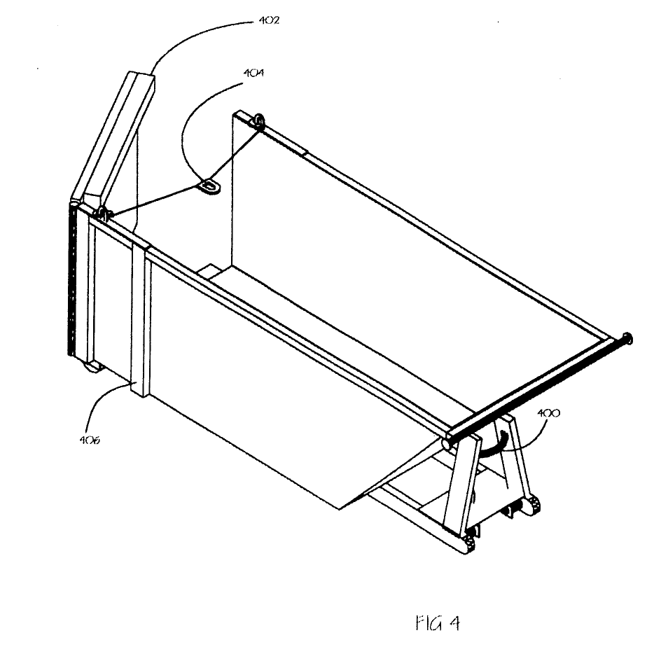

FIG. 3 is a side view of the first embodiment of the invention showing details of the gate. Gate lock arms 300 on the body have a hinged attachment to gate lock swing arms 302 on the gate. Open top container body 304 may be reinforced along the top edge, or by means of vertical ribs or the like.

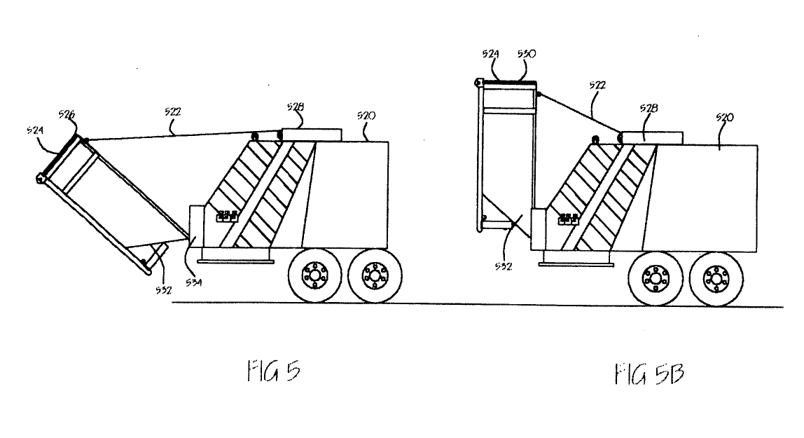

FIG. 4 is an elevational perspective view of the first embodiment of the invention with the gate partially open. Roll-off attachment point 400 may be seen to be an A frame suitable for use with the large mechanical hoist of a hoist truck.

Gate/cross beam 402 and rib 406 allow the device to be emptied in conventional fashion: the gate may be opened and the device emptied therethrough. The cross beam 402 is important for another reason: it is desirable to avoid physical deformation of the device in use. In particular, the sides of the device may crush towards each other under applied loads if a cross beam or a plurality of vertical ribs on the sides is not used. However, Y cable connector 404 allows the device to be fixed to the rear part of a rear load garbage truck by the trunnion bar and then lifted by a cable applied at the connector to the hard points.

This structure combination is not needed in any references having to do with small “DUMPSTER” containers, as the weight of a small container is small enough to allow easy attachments without fear of bending the sides inward. Thus the combination of full gate (for roll of use), beam across near the gate end, hard points near the beam ends and a Y-cable is un-necessary for small containers and unknown in the references.

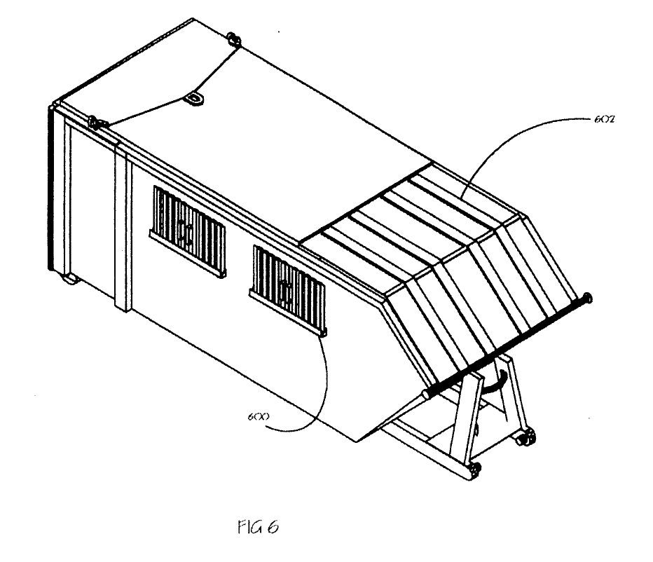

FIG. 5 is a side view of the first embodiment of the invention in a first raised position while FIG. 5b is a side view of the first embodiment of the invention in a second raised position to encourage gravity transfer of waste. In use, the trunnion bar of a container is customarily attached to the kick bar of the truck, allowing a firm attachment but also allowing rotation about the axis presented by the trunnion bar when so fixed.

Rear-load truck 520 has lift cable 522 attached directly or via pulley or lever arrangements to an otherwise standard hydraulic or electrical mechanical power source 528, which may be a hydraulic cylinder. Container 524 may be seen to be raised off of its normal ground position into first raised position 526 by the power of the hydraulic cylinder/waste handling power equipment 528 applied via cable 522 to the connector (not visible) and thence to the hard point and thus to the container body. Second raised position 530 may be seen. In the first raised position, the sloped front side nose 532 of the device is seen to be approximately level, while in the second raised position, the sloped front 532 is at an angle above the horizontal. Thus the first end of the device is raised to approximately the height of the hopper, while the second end is elevated to a height in excess of the height of the hopper.

It will readily be appreciated that the device will empty of waste under the influence of gravity, as the waste within gravity feeds into the hopper 534 of waste truck.

It will further be appreciated that this sequence of actions is somewhat startling in the industry. A roll-off container of 25′ length, 30′ length, or even more, and a capacity of 10 yards, 20 yards, 30 yards or even more, is raised nearly vertical behind a truck: this is completely dis-similar to standard front and rear load garbage truck operations and also to standard hoist truck operations.

It will further be readily be appreciated that a wide variety of container shapes and raised positions may be used. Front load garbage trucks may even be used.

Garbage trucks customarily come equipped with a number of waste handling power devices, and several of these devices are powerful enough that if their energy is redirected, they can easily lift a rear-load container off of the ground at one or both ends.

A winch hydraulic cylinder is depicted but several of the hydraulic cylinders of the standard rear-load garbage truck are powerful enough for the lift: the reeving cylinder, the kickbar cylinders, packer cylinders, etc. For the sake of clarity, it may be understood that the hydraulic pressure pump of a rear-load garbage truck may operate at 2500 PSI, thus providing enormous power which the present invention may direct. Cylinders which are not strong enough for the lift in standard rear-load garbage trucks may be upgraded in alternative embodiments of the invention so that they are strong enough for a container lift. Cylinders which travel in the wrong direction or are improperly disposed of upon the truck (for example, the ejector panel cylinder) may still be used if proper pulley arrangements are provided and motion can be “ratcheted” so that a very small cylinder motion may be made over and over again to sequentially drive the cable.

Thus the method of transferring waste according to the invention is as follows:
1) attaching the trunnion bar on the roll-off container to the hopper of the truck;
2) attaching a cable to the hard point of the roll-off container and to the hydraulic cylinder of the truck;
3) applying force to the cable from the cylinder so as to rotate the roll-off container vertically about the trunnion bar;
4) raising the second end of the roll-off container to a height higher than the height of the hopper, whereby the container gravity feeds into the hopper.

A lock and latch may secure the roll-off container to the rear-load truck hopper.

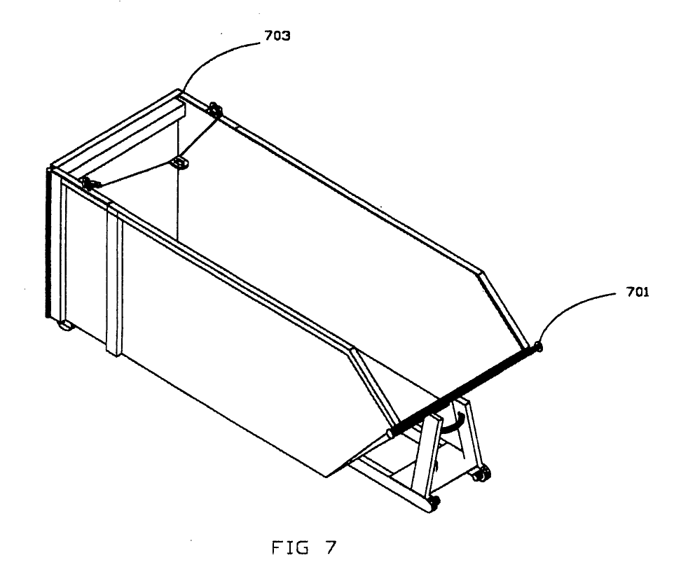

FIG. 6 is a perspective view of a second embodiment of the invention, a compactor embodiment.

Side waste load door 600 allows waste to be loaded from the side, while folding top door 602 allows the device to flow out when in a raised position. This device may be a simple covered container or it may have compaction equipment within it allowing it to compact waste independently of the garbage truck.

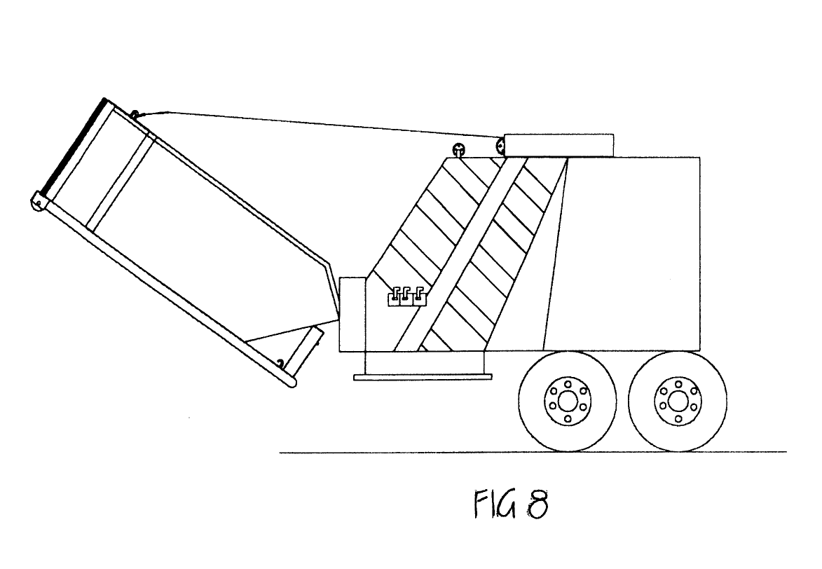

FIG. 7 is an elevational perspective view of a 15 yard container embodiment having higher sides. This embodiment allows a greater volume of waste to be placed within the device. It will be appreciated that containers of smaller sizes may be serviced by this method, although such containers may be raised and tilted by conventional means already. It will be appreciated larger containers may also be used. Second end 703 having a gate and first end 701 having an axis of rotation (in this embodiment a trunnion bar) are shown.

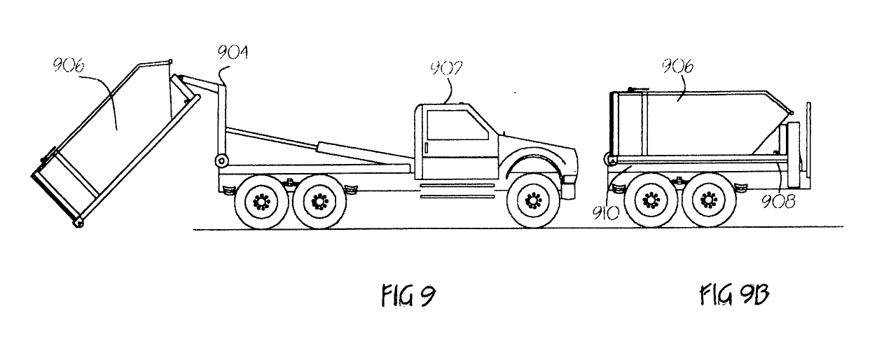

FIG. 8 is a side view of a larger embodiment of the invention in the course of transfer to a rear-load truck.

FIG. 9 is a side view of a hoist truck and the container of the invention, showing the invention in the process of being lifted onto the roll off truck for conventional roll-off processing and FIG. 9b is a partial side view of the invention on the roll off truck, showing it in the position for conventional conveyance.

In the preferred embodiment and best mode now contemplated, the invention is equipped with roll-on/roll-off equipment. Guide rails slide onto and off the tracks of a hoist truck, when the unit is being moved or when it is being serviced by a hoist truck rather than a rear-load garbage truck. Rollers are also necessary or useful for this process. A hook may be part of either the traditional cable style hoist system or part of the newer style hook box design. In other embodiments, roll-on/roll-off equipment is not needed. It will be appreciated that the invention may be embodied in a wide variety of waste containers: commercial size bins, (“DUMPSTERS”) other sizes and shapes of bins, non-roll-off containers, small trash cans, and so on, but such smaller containers may already be serviced by non-hoist trucks. The use of large containers is what sets the invention apart commercially from conventional systems.

Roll off truck 902 is depicted as a hoist truck but may be a cable truck or any kind of roll off truck now known or later devised. Hoist 904 lifts container 906 onto truck bed 908, which may be seen to have truck bed rails 910 which cooperate with the rollers beneath the bottom of the container 906 to allow the container to easily slide forward into the rest position for transportation.

Embodiments having different bar arrangements in the “nose” of the invention may cooperate differently with the hopper and may have different axes of rotation than only a trunnion bar.

While the gate may lift vertically, other types of doors may be used, depending upon the receiving vehicle, space requirements and other considerations. For example, in embodiments the door may be hinged at the top or may swing (side-hinged) or may open in other ways. While in the preferred embodiment hydraulic cylinders are used to raise the gate, hydraulics, electrics or other devices may be used to open the gate, or it may operate manually, or (for example in the top-hinged embodiment) the gate may have a strong retaining spring which urges the door shut until greater pressure is applied by means of a transfer or ejector mechanism. The back end, having the gate, may function as both a door and a gate: it may open both vertically upwards and yet also swings sideways. Use as a gate, possibly hydraulically actuated, allows the container to be serviced in several different ways. Use as a door is advantageous because it allows the invention to function as a known roll-off container: the operator may hoist it onto a hoist-truck, convey it to a land-fill facility, open the door manually, and raise it to dump the contents.

The width of the invention's body is of importance. If the body is considerably wider than the waste receptacle of the receiving garbage truck, during ejection it may spill wastes out on one or both sides of the garbage truck, or, as is the case with front load containers from the Pickering reference cited previously, a device with sleeves on the side is most likely impossible to use with a rear-load truck hopper at all. If it is considerably narrower, the process may be unduly prolonged and the container may be of excessive length or height in order to compensate. Thus in one embodiment of the invention, the width of the body of the invention is approximately the same as the width of the waste receptacle or hopper of the garbage truck servicing the invention. In another embodiment, the width is just less than that of the truck hopper. This width may range from 36 inches to 98 inches, more preferably from 60 inches to 84 inches, most preferably from 70 to 72 inches. These widths are approximations, of course, as equipment on the garbage truck may project inwards and thus effectively narrow the hopper. For example, on one model of truck the trunnion latches may have posts projecting towards the centerline of the hopper, thus reducing a 72 inch hopper to an effective width of 71 inches in that spot. The term “approximately equal” includes a body slightly narrower or wider than the truck's waste receptacle to account for such equipment, for the efficiency of having the body be very slightly narrower than the receptacle in order to make backing up to the container easier and transfer more tidy, and so on.

In the preferred embodiments the servicing garbage truck provides compaction. Compaction of the waste by the servicing truck is desirable for several reasons. First, it obviates the need for compaction devices at each waste container: the compaction device in the truck is brought to each container in turn. Secondly, such compaction (at a ratio ranging from as little as 2 to 1 to as much as 20 to 1, with 10 to 1 being the favored ratio) is desirable in order reduce waste volume. Since most sanitary landfill operators charge by volume, this in turn reduces the costs to the disposal contractor. Stationary compactors usually have a compaction ratio of only 3 to 1, which does not compare favorably to the 7 to 1 ratio of a front load truck and the 10 to 1 or more ratio of the standard rear-load garbage truck.

However, the container serviced may also be a compactor in embodiments.

Containers which may be used with the present invention will normally range in size from 10 to 20 to cubic yards, however, the invention may be implemented with smaller containers, of which there are a multiplicity of known sizes: 6.5 cubic yards, 7.6 cubic yards and so on, or with larger containers such as 30 to 40 yard containers or even larger.

In terms of energy usage, a large truck making multiple daily round-trips to the landfill represents a large use of petroleum products or other energy sources. By means of the present invention, the number of such trips may be dramatically reduced, and the trucks making the trip may be converted from roll-off hoist trucks to ordinary garbage trucks. The compaction of waste at 3 to 1, 10 to 1 or even 20 to 1 means that many trips can be saved. In every metropolitan area, there are fleets of such trucks capable of doing this by means of the present invention. Thus, the present invention offers the ability to provide great energy savings. In addition to fuel, the environmental aspect of this is quite large. The emissions generated by a single truck may be greatly reduced by use of the present invention. Such airborne pollution is becoming a greater issue due to global warming, depletion of the ozone layer, metropolitan growth and an increased understanding of the health hazards of such air pollution.

The method of the present invention is also susceptible to various embodiments which may further reduce energy usage. In one alternative embodiment, the waste received by the waste container of the invention may come from another waste container, a garbage truck, or similar waste handling device. By this means, the invention may advantageously serve as an intermediate transfer station between the initial waste receptacle and the final land-fill facility. For example, this embodiment may advantageously be used in a situation in which the waste handling contractor has to service numerous small waste receptacles (such as commercial size containers). It may not be commercially feasible to travel to the landfill facility each time the garbage truck or a conveyor vehicle (such as one which carries several smaller waste containers on its bed or in other special equipment) becomes full to capacity, especially if the land-fill facility is far from the waste containers to be serviced. In that event, the waste handling contractor may transfer waste from small containers (or even a truck) to the invention, then make a reduced number of round trips to the land-fill facility. Waste placed in the waste container may come from a source selected from the group consisting of: smaller waste containers, garbage cans, commercial waste containers, rear-load garbage trucks, front-load garbage trucks, hoppers, waste receptacles, and combinations thereof. Thus, another method of energy savings is taught by use of the present invention.

The disclosure is provided to allow practice of the invention by those skilled in the art without undue experimentation, including the best mode presently contemplated and the presently preferred embodiment. Nothing in this disclosure is to be taken to limit the scope of the invention, which is susceptible to numerous alterations, equivalents and substitutions without departing from the scope and spirit of the invention. The scope of the invention is to be understood from the appended claims.

What is claimed is:

1. A waste handling system for use with a rear-load garbage truck having a waste receiving hopper at a first height, and having waste handling power equipment having a first position and a second position, the waste handling system comprising:
an operative physical link having a connector; the operative physical link connected to such power equipment;
a roll-off container having an elongated body of at least 10 yards capacity having two ends, and having roll-off equipment including a first standard roll-off hook, and at least one skid and at least one roller, and having a gate located at the second end of the body, and having at least one cross beam spanning the body, the cross beam reinforcing first and second sides of the container body;
a Y cable connector located at the cross beam at the first and second sides, the Y cable connector dimensioned and configured to accept the connector;
the operative physical link dimensioned and configured such that when the connector of the operative physical link is attached to the Y cable connector and such power equipment is changed from such first position to such second position, at least the second end of the body is lifted to approximately such height of such hopper.

2. The waste handling system of claim 1, wherein the width of the hopper and the width of the body are approximately equal.

3. The waste handling system of claim 1, wherein the width of the hopper and the width of the body are in the range from 70 to 72 inches.

4. The waste handling system of claim 1, wherein the second end of the body is lifted substantially higher than the height of the hopper.

5. The waste handling system of claim 1, wherein the power equipment comprises a hydraulic cylinder.

6. The waste handling system of claim 5, wherein the hydraulic cylinder comprises a winch cylinder.

7. The waste handling system of claim 6, wherein the power equipment comprises a compactor blade.

8. The waste handling system of claim 1, wherein the operative physical link comprises a cable.

9. The waste handling system of claim 1, wherein the first hook further comprises at least one member selected from the group consisting of: a roll-off hoist arm receiver hook, a roll-off cable receiver hook and combinations thereof.

10. A waste handling system for use with a rear-load garbage truck having a waste receiving hopper at a first height, and having waste handling power equipment having a first position and a second position, the waste handling system comprising:
an operative physical link having a connector; the operative physical link connected to such power equipment;
a roll-off compactor comprising:
a body having first and second ends and a full roll-off gate spanning the second end, and having a beam spanning the second end;
roll-off equipment including a first hook, and at least one skid and one roller;
a Y cable connector located at the second end of the body, the Y cable connector dimensioned and configured to accept the connector;
the operative physical link dimensioned and configured such that when the connector of the operative physical link is attached to the Y-cable connector and such power equipment is changed from such first position to such second position, at least the second end of the body is lifted to approximately such height of such hopper.

11. A method of transferring waste from a roll-off container having standard roll-off equipment including an elongated body of at least 15 yards capacity having first and second ends, a roll-off hook, at least one skid and one roller, and a full gate spanning the second end; the roll-off container further having a trunnion bar at the first end and a hard point to a standard garbage truck having a hopper at a first height above the ground and at least one hydraulic cylinder, the process comprising the steps of:
1) attaching the trunnion bar on the roll-off container to the hopper of the truck;
2) attaching a cable to the hard point of the roll-off container and to the hydraulic cylinder of the truck;
3) applying force to the cable from the cylinder so as to rotate the roll-off container vertically about the trunnion bar;
4) raising the second end of the roll-off container to a height higher than the height of the hopper, whereby the roll-off container gravity feeds into the hopper over the lip of the first end.
